(19) United States
(12) Patent Application Publication
(10) Pub. No.: US 2012/0326096 A1
(43) Pub. Date: Dec. 27, 2012

(54) THERMOELECTRIC MATERIALS COMBINING INCREASED POWER FACTOR AND REDUCED THERMAL CONDUCTIVITY

(75) Inventors: Lon E. Bell, Altadena, CA (US); Dmitri Kossakovski, South Pasadena, CA (US)

(73) Assignee: ZT PLUS, Azusa, CA (US)

(21) Appl. No.: 13/601,967

(22) Filed: Aug. 31, 2012

Related U.S. Application Data
(62) Division of application No. 12/429,841, filed on Apr. 24, 2009.
(60) Provisional application No. 61/058,125, filed on Jun. 2, 2008.
(60) Provisional application No. 61/047,691, filed on Apr. 24, 2008.

(51) Int. Cl. H01L 31/0352

(52) U.S. Cl. 252/500

(57) ABSTRACT

A thermoelectric material and a method of forming a thermoelectric material are provided. The method of forming a thermoelectric material includes providing at least one compound fabricated by a first technique and having a first power factor and a first thermal conductivity. The method further includes modifying a spatial structure of the at least one compound by a second technique different from the first technique. The modified at least one compound has a plurality of portions separated from one another by a plurality of boundaries. The plurality of portions include one or more portions having a second power factor not less than the first power factor, and the modified at least one compound has a second thermal conductivity less than the first thermal conductivity.

### CLAIM OF PRIORITY

This application is a divisional of U.S. patent application Ser. No. 12/429,841, filed Apr. 24, 2009 and incorporated herein in its entirety by reference, which claims the benefit of U.S. Provisional Application No. 61/047,691 filed Apr. 24, 2008 and of U.S. Provisional Application No. 61/058,125 filed Jun. 2, 2008, which are incorporated herein in their entireties by reference.

### BACKGROUND

It has previously been predicted that the Power Factor (equal to the Seebeck coefficient squared multiplied by the electrical conductivity, e.g., S²σ) of thermoelectric (TE) materials can be increased by doping a parent, common TE compound (e.g., PbTe) with dopants that distort the electronic density of states (DOS) and pin the Power Factor of the compound and that create resonant energy levels, thereby increasing the Power Factor of the material. [See, e.g., G. D. Mahan and J. O. Sofo, Proc. Natl. Acad. Sci. USA 93, 7436 (1996).] The lattice thermal conductivity of the compound is not significantly affected by such doping. Throughout this application, “lattice thermal conductivity” is defined as a portion of total thermal conductivity that contains all the non-electronic contribution to the total thermal conductivity. Therefore, such Fermi level pinning will yield an improved figure of merit of the TE material, ZT. Other mechanisms, or a combination of mechanisms for DOS distortions may be accountable for similar effects of ZT improvement; e.g. having more than one conduction band or valley accessible to charge carriers at a given carrier concentration and/or temperature.

An alternative approach to increase the Power Factor of a TE compound was previously demonstrated via electron filtering by creation of optimized metal-semiconductor Schottky barriers. [D. Vashaee and A. Shakouri, “Improved Thermoelectric Power Factor in Metal-Based Superlattices,” Physical Review Letters, 92(10), 106103, 12 Mar. 2004; J. M. O. Zide et al., “Demonstration of electron filtering to increase the Power Factor in In_{0.53}Ga_{0.47}As/In_{0.53}Ga_{0.28}Al_{0.19}As superlattices,” Phys. Rev. B 74, 205335 (2006).]This approach had the beneficial side effect of lowering the thermal conductivity via scattering of long wavelength phonons. Both the increased Power Factor and the reduced thermal conductivity created by the electron filtering lead to improved ZT of the material.

Another way to improve the ZT of a TE compound is by lowering the lattice thermal conductivity of the compound. For example, such an effect could be achieved by creating a spatial structure within the compound with features having a characteristic size comparable to the wavelength of phonons that transport significant heat within the compound. Such spatial inhomogeneity can suppress the propagation of phonons without significantly affecting the transport of electrons. Examples of such inhomogeneous structures include but are not limited to, superlattices, bulk and composite materials, embedded particles, material systems with density fluctuations, spinodal phase decompositions, self-ordered phase separations, phase separations by nucleation and nano-scale growth, and other structures with engineered, non-uniform compositions on a nanometer and/or micrometer scale.

### SUMMARY

In certain embodiments, a method of forming a thermoelectric material is provided. The method includes providing at least one compound fabricated by a first technique and having a first power factor and a first thermal conductivity. The method further includes modifying a spatial structure of the at least one compound by a second technique different from the first technique. The modified at least one compound having a plurality of portions separated from one another by a plurality of boundaries. The plurality of portions include one or more portions having a second power factor not less than the first power factor, and the modified at least one compound has a second thermal conductivity less than the first thermal conductivity.

In certain embodiments, the boundaries include grain boundaries and the one or more portions having the second power factor comprise two or more portions. In certain embodiments, the second technique includes forming the plurality of portions into a plurality of particles and consolidating the plurality of particles. In certain embodiments, the particles have a grain size that preserves the electronic properties of the at least one compound. In further embodiments, substantially each of the plurality of particles have a stoichiometry that is substantially the same as a stoichiometry of the at least one compound.

In certain embodiments, the boundaries include phase boundaries and the plurality of portions comprises a first portion having the second power factor and a plurality of second portions which are surrounded by the first portion. In certain embodiments, the at least one compound includes a first composition selected such that after the second technique is performed, the first portion includes a second composition having selected electronic properties. In certain embodiments, the phase boundaries are formed by nucleation and growth. In further embodiments, the phase boundaries are formed by nucleation and growth.

In certain embodiments, a thermoelectric material is provided. The thermoelectric material includes at least one compound including at least one dopant such that the at least one compound includes one or more portions having a Power Factor greater than a Power Factor of the at least one compound without the at least one dopant. The at least one compound includes a spatial structure characteristic such that the at least one compound has a lattice thermal conductivity coefficient less than a lattice thermal conductivity coefficient of the at least one compound without the spatial structure characteristic.

In certain embodiments, the spatial structure characteristic includes one or more spatial inhomogeneities. In further embodiments, the one or more spatial inhomogeneities have a characteristic size comparable to phonon wavelengths contributing to the lattice thermal conductivity of the at least one compound. In certain embodiments, the one or more spatial inhomogeneities include composition variations of the at least one compound. The composition variations can include phase separation of the at least one compound into at least two phases. In certain embodiments, the at least one compound includes a plurality of grains and the spatial structure characteristic includes a minimum grain size such that substantially all of the grains of the at least one compound are larger than the minimum grain size. In further embodiments, the minimum grain size is sufficiently large to preserve the bulk stoichiometry of the at least one compound.

### BRIEF DESCRIPTION OF THE DRAWINGS

FIG. 1 is a flow diagram of an example method of providing at least one compound and modifying a spatial structure of the at least one compound in accordance with certain embodiments described herein.

FIG. 2 is a flow diagram of an example method of providing at least one compound, fabricating the at least one compound by a first technique, and modifying a spatial structure of the at least one compound by a second technique in accordance with certain embodiments described herein.

FIG. 3 is a flow diagram of an example method of determining a minimum grain size based on a composition of the at least one compound, forming particles of the at least one compound having a selected grain size, and reconsolidating the particles to form a modified at least one compound with the selected grain size in accordance with certain embodiments described herein.

FIG. 4 is a flow diagram of an example method of selecting starting composition of the at least one compound to compensate for subsequent processing, and forming a first phase and a second phase of the at least one compound wherein the first phase being a selected composition in accordance with certain embodiments described herein.

### DETAILED DESCRIPTION

Typically, greater Power Factors are shown by plotting the Seebeck coefficient against the carrier concentration (known as a Pisarenko plot). Materials with increased Power Factors are represented by data points positioned above regular Pisarenko plots, thereby denoting that the material has a higher Seebeck coefficient for a given carrier density. The increase of the Power Factor is manifested by compounds having a higher Seebeck factor for a given carrier density compared to the compounds without such dopants. In some compounds, the Power Factor increase is exhibited by a constant, or not substantially changing, Seebeck coefficient within a range of carrier densities.

The figure of merit ZT is generally used to characterize thermoelectric materials, where ZT=TS²σ/κ, and S is the thermoelectric power or Seebeck coefficient of the TE material, σ and κ are the electrical and thermal conductivities, respectively, and T is the absolute temperature. Several publications disclose producing high ZT materials using two general approaches: either by increasing the Seebeck coefficient or the Power Factor (e.g., via Fermi level pinning or electron filtering) or by reducing the thermal conductivity of the materials, such as high Gruneisen parameter materials (e.g., by spinodal deposition, nanoscale sintering, zintl structures, etc.). While each of these approaches have promise, substantial further gains can be achieved by combining the improved Seebeck/power factor with decreased thermal conductivity.

However, mere combinations of these two approaches would result in less-than-optimal improvements of ZT, an effect which is not addressed in the previous publications. For example, the methods for DOS distortions rely on developing specific doping materials and concentrations in the proper crystalline structure. The states which distort the DOS are sensitive to doping concentration levels and to the presence of other constituents which can alter the structure or the valence states of the doped compounds.

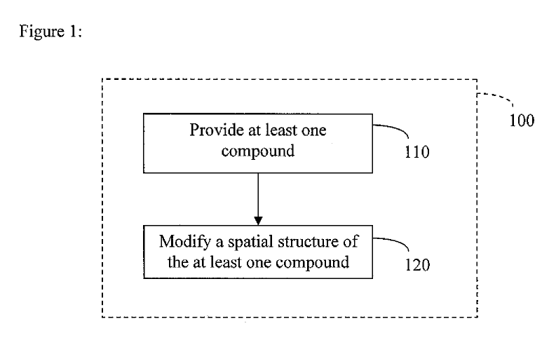

Certain embodiments include methods of forming a thermoelectric material with an improved ZT. FIG. 1 is a flow diagram of an example method 100 of forming a thermoelectric material with an improved ZT in accordance with certain embodiments described herein. The method 100 includes providing at least one material or compound fabricated by a first technique, as in operation block 110. The at least one material has a first power factor and a first thermal conductivity. The method 100 further includes modifying a spatial structure of the at least one material or compound by a second technique different from the first technique, as shown in operation block 120. The second technique produces a plurality of portions in the at least one material or compound separated from one another by boundaries. At least one or more of the portions have a second power factor not less than the first power factor, and the at least one material or compound has a second thermal conductivity less than the first thermal conductivity. The boundaries can include grain boundaries or phase boundaries.

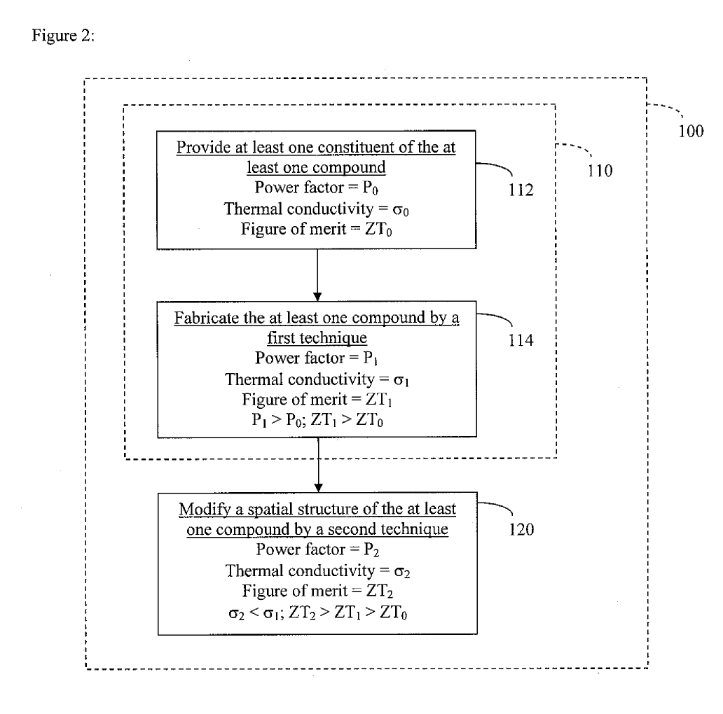

FIG. 2 is a flow diagram of an example method 100 of forming a thermoelectric material with an improved ZT in accordance with certain embodiments described herein. In the method 100 of FIG. 2, forming the at least one compound of operation block 100 includes providing at least one constituent of at least one compound in operation block 112 and fabricating the at least one compound by a first technique in operation block 114. The at least one compound initially has a Power Factor of P₀, a thermal conductivity of aₒ and a figure of merit of ZT₀ and after the operation block 114, the at least one compound has a Power Factor of P₁, a thermal conductivity of σ₁ and a figure of merit of ZT₁. In certain embodiments, P₁ is greater than P₀ and/or ZT₁ is greater than ZTₒ. In operation block 120, the at least one compound is modified with a spatial structure by a second technique. The at least one compound after the second technique has a Power Factor of P₂, a thermal conductivity of σ₂ and a figure of merit of ZT₂. In certain embodiments, σ₂ is less than σ₁ and/or ZT₂ is greater than ZT₁. In certain embodiments, operational blocks 112, 114 and 120, or any combination thereof, can be performed in the same step. For example, the first technique and the second technique can be performed in the same step.

For example, the second technique (different from the first technique used to fabricate the TE material having the enhanced Power Factor) can be used to modify a spatial structure of the TE material. In certain such embodiments, after the second technique is performed, the TE material has a plurality of portions separated from one another by a plurality of boundaries. In certain such embodiments, the plurality of portions comprises one or more portions having a Power Factor that is not less than the Power Factor of the TE material before the second technique is performed. In certain such embodiments, the TE material after the second technique is performed has a thermal conductivity less than the thermal conductivity of the TE material before the second technique is performed.

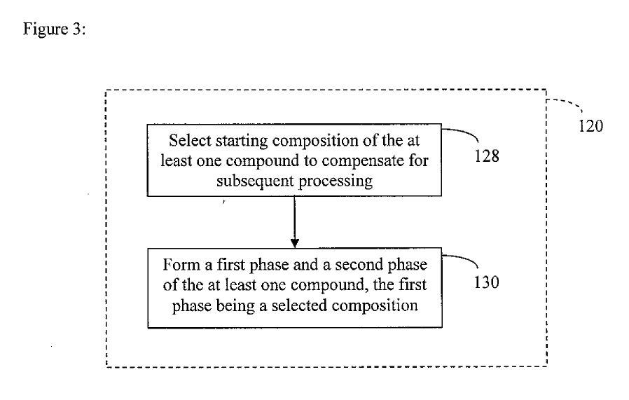

For example, the boundaries can comprise phase boundaries and the plurality of portions can comprise at least one portion (e.g., a main or primary phase portion) having the enhanced Power Factor (e.g., not less than the Power Factor of the TE material before the second technique is performed) and a plurality of portions (e.g., at least one second or secondary phase portion) within and surrounded by the at least one portion. FIG. 3 is a flow diagram of an example method or operation block 120 which uses phase boundaries as a spatial structure. In operation block 128, a starting composition of the at least one compound is selected to compensate for subsequent processing. In operation block 130, a first phase and a second phase of the at least one compound are formed wherein the first phase is a selected composition. Operational blocks 128 and 130 do not necessarily have to be performed in a particular order. For example, selecting a starting composition of the at least one compound to compensate for subsequent processing can be performed before providing at least one compound, and forming a first phase and a second phase of the at least one compound can be performed during or after fabricating the at least one compound by a first technique.

In certain embodiments, the phase boundaries between the at least one main phase portion and the secondary phase portions can be formed by spinodal decomposition or by nucleation and growth (e.g., by nucleation occurring at grain boundaries). In certain embodiments, the composition of the TE material before the second technique is performed is selected such that after the second technique is performed, the at least one portion comprises a different composition having selected electronic properties. For example, in certain embodiments in which these materials are altered by adding a separate constituent to form a spinodal decomposition, the concentration of the at least one dopant is advantageously selected to effectively benefit from the formation of a second (spinodal) phase to the lower thermal conductivity. In certain embodiments in which the at least one dopant selectively migrates to the spinodal sites, a change in dopant level is advantageously used to give the proper dopant level in the base material. In certain embodiments in which the at least one dopant reacts adversely with the second (spinodal) phase, at least one of the dopant or the second phase is advantageously selected or altered (e.g. one or more constituents of the second phase) to achieve compatibility. In certain embodiments in which the at least one dopant selectively migrates or reacts adversely, the proper material system is advantageously developed by modeling and computing energy states for candidate materials in projected crystalline structure of the final material system, and designing for high ZT properties. The kinetics of the decomposition of the structural modification can create boundaries or additional phases that increase carrier scattering. In certain embodiments, the kinetics can be adjusted by various techniques, including but not limited to, changing the composition, changing the decomposition time and/or the temperature relationship by adding one or more additional heat treatment conditions to re-dissolve the boundary phase, by adding constituents to create extra nucleation sites to speed up the desired precipitation or to slow down the undesired effects, by adding other constituents that prevent unwanted decomposition, or by incorporating any other method that maintains or enhances carrier mobility or the Seebeck coefficient.

Similarly, in certain embodiments in which the dopant is essentially immiscible in the second phase, the concentration is advantageously adjusted to achieve effective dopant levels and Seebeck/power factor levels in the matrix phase of the final material. In certain such embodiments in which the result is complicated by the possibility that the second phase may interact with the matrix phase through the electron work function at the interface, further adjustment or composition change is advantageously made to compensate. Thus in certain embodiments, the composition and/or concentration levels that create the higher Seebeck/power factor in the base matrix material are adjusted to compensate for the addition of a second phase that reduces thermal conductivity.

Certain embodiments described herein relate to a class of thermoelectric materials that possess enhanced performance characteristics through a combination of increased Power Factor and reduced lattice thermal conductivity. All the concepts for enhanced ZT outlined herein are applicable to heating and cooling and refrigeration materials (low temperature applications) and power generation materials (high temperature applications).

In certain embodiments, the ZT of TE materials can be enhanced even further by combining the methods and techniques targeting the enhancement of the Power Factor with the methods and techniques targeting the lowering of the lattice thermal conductivity. This combination can be achieved by a variety of methods, at least some of which are described below.

For example, the boundaries can comprise grain boundaries with a plurality of grains with a Power Factor not less than the Power Factor of the TE material before the second technique is performed. In certain embodiments, the second technique can comprise transforming a material with a Power Factor enhanced by electron filtering and/or DOS distortion into particles (e.g., by grinding or ball milling) which are then spark sintered, hot pressed, or otherwise reconsolidated. In certain embodiments, the thermal conductivity reduction is achieved by phonon scattering due to the presence of nano- or micro-scale grain structures and/or grain boundaries. The particle shape can be spherical, oval, wire-like, rod-like, platelet, connected in beads or chains, or in any other shape that enhances the Power Factor and/or transport properties and/or reduces thermal conductivity.

In certain embodiments, TE material can comprise one or more spatial inhomogeneities (e.g., grains, particles, or composition variations of the TE material) comprising a characteristic size or length. For example, the spatial inhomogeneities can be formed by embedding particles of at least a first compound in a matrix of at least a second compound, or by creating a plurality of pores in the TE material. In certain such embodiments, the characteristic size or length is comparable to phonon wavelengths contributing to the lattice thermal conductivity of the TE material after the second technique is performed. The spatial inhomogeneities can suppress propagation of phonons within the TE material.

For example, in certain embodiments, the thermal conductivity of TE materials can be beneficially lowered by creating nanometer-sized powders from the parent crystalline materials and then consolidating powders into solids. Although the electronic properties of the TE material are generally considered to be unaffected by nano-powdering, it is more usual that the thermal properties are affected. In certain such embodiments, changes of composition, shape or other attributes are advantageously made to achieve the predicted enhancement in performance. In certain embodiments, the physical cause for thermal conductivity reduction is the scattering of phonons at the powder grain boundaries. ZT will increase if there is little or no corresponding change in the scattering of electrons.

In certain embodiments, the powders can be made by applying a mechanical force to the compound (e.g. grinding or ball milling), melt spinning, rapid quenching or any other suitable technique. The consolidation can be done by hot or cold pressing, sintering (possibly assisted by DC current or plasma spark discharge), a combination of these techniques, or any other suitable technique. It is a general desire in the material research community to minimize the grain size in order to improve the phonon scattering. For example, Poudel et al. (Poudel, B. et al., “High-Thermoelectric Performance of Nanostructured Bismuth Antimony Telluride Bulk Alloys”, www.sciencexpress.org/20March2008/10.1126/science.1156446) mentions the grain sizes with linear dimensions from below 5 nm to ˜50 nm as contributing to the thermal conductivity improvement.

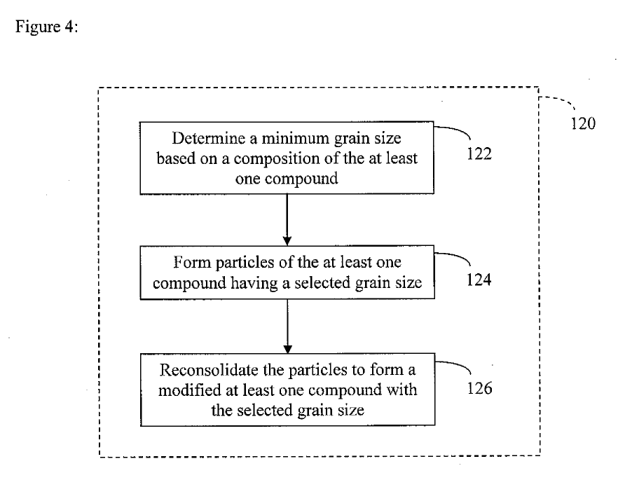

It is important to note that when the grain size becomes comparable to lattice constants of the parent material, the stoichiometry of the material and dopant concentrations may affect the minimum grain size that will still act as a thermoelectric material with desired electronic properties. Generally, in smaller grains, the dopant concentration and material stoichiometry can be perturbed compared to the parent material with possible negative effects to the material performance. FIG. 4 is a flow diagram of an example method or operation block 120 which uses grain boundaries as a spatial structure. In operation block 122, a minimum grain size is determined based on a composition of the at least one compound. In operation block 124, particles of the at least one compound are formed having a selected grain size. In operation block 126, the particles are reconsolidated to form a modified at least one compound with the selected grain size. Operational blocks 122, 124 and 126 do not necessarily have to be performed in a particular order. For example, determining the minimum grain size based on a composition of the at least one compound can be performed before providing at least one compound. In certain embodiments, the minimum grain size is such that the stoichiometry of individual grains is substantially the same as the stoichiometry the material or compound in bulk. In further embodiments, substantially all of the grains of the material or compound are larger than the minimum grain size. In certain embodiments, the particles comprise a grain size that preserves the electronic properties of the TE material before the second technique is performed. For example, in certain embodiments, the dopant concentration of substantially each of the plurality of particles is substantially the same as the dopant concentration of the TE material before the second technique is performed. In certain such embodiments, substantially each of the plurality of particles comprises a stoichiometry that is substantially the same as the stoichiometry of the TE material before the second technique is performed.

As an example, in PbTe where 1% of lead is replaced by a dopant of interest (e.g., Tl or Na), the chemical composition of the material becomes Pb_{0.99}Tl_{0.01}Te in case of Tl doping. PbTe has a rock salt (cubic) crystal structure. In the 1% Tl-doped material, Tl will replace one of every 100 Pb atoms in the nodes of the crystal lattice. The lattice constant for PbTe (the distance between two adjacent atoms of Pb and Te) is a well known value (equals 0.646 nm at the temperature of 300 K). The doping by Tl will perturb this value, but at the low doping levels, this perturbation is insignificant and can be neglected.

Using the lattice constant, the crystal volume per one Pb atom can be calculated to be about 0.135 nm³. Therefore, a grain with at least 100 Pb atoms (and presumably a grain with at least one Tl atom per 99 atoms of Pb) should have a volume of about 13.5 nm³. If the dopant distribution were absolutely homogenous, then this value would correspond to a minimum grain size that preserves the desired electronic properties of the material.

However, the boundary effects will affect the electronic structure of the grains, and there will also be certain statistical distribution of the dopant atoms throughout the sample. With these effects in mind, in certain embodiments, the minimum grain size is selected to be a multiple of the size of the elementary crystal cell. For example, for the Pb_{0.99}Tl_{0.01} Te system described above, advantageously the minimum grain size can be selected to be between 2 to 10 times that of the volume occupied by 100 Pb atoms. Therefore, in this example, the corresponding grain volume should be about 27 to 135 nm³ to preserve desired electronic structure of the material. As such, the gain volume can be selected to be between ten and one hundred times the minimum volume to preserve the bulk stoichiometry of the material or compound. For a spherical grain, this volume corresponds to the grain diameter of about 3.0 to 7.6 nm, which is within the range of grain sizes reported by Poudel.

The example above considers only one particular crystal structure with a corresponding lattice constant as well as a particular particle shape. Other materials can have different crystal structures, different lattice constants and different dopant levels. Shape can vary widely, including rod, wire, platelet, ellipsoid, irregular, size distributions of any shape, and combinations of shapes. However, the general considerations described above are applicable to any TE material with grain structure in the nanometer scale. The minimum grain size for a TE material below which the electronic structure of the material will be perturbed is determined by the crystal geometry and stoichiometry of the material.

Another consideration on how the size of the grain may affect the thermoelectric properties of the material is related to the charge transport by electrons and holes. In some semiconductor materials, both types of free charge carriers are present. If an electric field is applied to such material in a bulk form, both types of carriers move and the net resulting current (and heat transfer) can be small. However, if the material has a grain, or another type of structure that has a characteristic size or length in between the mean free path of electrons and holes (electrons typically have longer mean free path), then upon the application of electric field, the holes will be scattered while electrons will propagate freely. This will lead to improved charge transport characteristics of the material, ultimately rendering it to be a better TE material.

In certain embodiments, it is advantageous to make changes in materials whose ZT, and/or other properties could benefit from nanoscale particle size formation and subsequent reconsolidation, for similar reasons. For example, if the beneficial dopant that increased the high Seebeck/power factor has a different (e.g., higher or lower) solubility at grain boundaries, the dopants can be changed, other doping agents can be added, or concentrations can be adjusted to compensate. The selection process will depend on the characteristics of the system, but it will often be advantageous to model the electronic structure and compute the resulting characteristics of potential agents at several concentrations. Also, in certain embodiments in which the dopants cannot be changed, or in which it is otherwise not advantageous to change them, the basic material composition can be modified to accommodate both methods of ZT enhancement. This would be the case if added agents promoted sintering, increased nano scale composition stability, promoted electron mobility or had any other beneficial effect.

Alternatively, in certain embodiments, the thermal conductivity can be decreased by creating a multitude of micro- and nano-sized pores of advantageous shapes in the TE compound, serving as scattering centers for phonons. Such structures can be engineered to have little or no reduction of the electron mobility of the TE compound. Such porous, foamy structure can have multiple characteristic length scales, possess fractal structure, and be close to percolation threshold. Advantageously, in certain embodiments, the sizes of the voids are generally comparable with the phonon wavelengths that correspond to a large fraction of the total phonon heat transport in the TE compound. In certain such embodiments, the voids are efficient scatterers of the phonons.

Alternatively, in certain embodiments, a second, discrete phase can be added to the TE compound to suppress the lattice thermal conductivity (e.g. suppress propagation of phonons in the compound). The presence of this phase, and the details of its spatial organization relative to the first phase with particle size distribution, shape, and density can be selected to reduce the thermal conductivity of the TE compound. In certain embodiments, spatial inhomogeneities include composition variations of the compound. An example of such a second phase in accordance with certain embodiments described herein are PbSe quantum dots incorporated in the structure of PbTe by means of molecular beam epitaxy. [See, e.g., T. C. Harman et al., Science 297, pp. 2229-2232, 2002.] The properties of such a material can be enhanced further in certain embodiments by adjusting the electronic properties of the particles to reduce electron scattering and/or enhancing electron filtering.

Another approach compatible with certain embodiments described herein is to create a two-phase material by precipitation techniques, such as spinodal decomposition or nucleation and growth. [See, e.g., J. Androulakis et al., J. Am. Chem. Soc. 129, 9780-9788, 2007.] For two-phase materials, the nucleation and growth of the second phase can occur in certain embodiments at the grain boundaries of the first phase. If at least one of the resultant phases either retains enhanced Seebeck properties or acquires enhanced Seebeck properties during processing, then the resultant material can advantageously derive the benefit of the combined increased Power Factor and reduced thermal conductivity. For example, one of the resultant phases can have enhanced TE properties via Fermi level pinning or any other suitable DOS distortion through appropriate doping. Alternatively, one phase can have an increased Power Factor via electron filtering, which can occur either within the phase or at the phase boundaries.

In certain embodiments, the material or compound may be mechanically weakened by the addition of a dopant (e.g. Tl in PbTe) in the large concentrations that maximize ZT. The addition of a second phase (or other spatial structural characteristics) that reduces thermal conductivity, such as through spinodal decomposition, can also advantageously strengthen and/or mechanically stabilize (e.g. increase fracture toughness, hardness and/or yield strength) the resulting composite material or compound. Other methods of improving ZT, such as by intentionally altering carrier concentrations off-stoichiometry, can also lead to weaker materials. In certain such embodiments, the resulting materials can benefit from one or more material additions that result in reduced thermal conductivity and/or increased power factor while hardening the composition. Examples are through spinodal decomposition, mechanical addition of a second phase within the primary TE material, disbursing nano-scale phase(s) that create phonon scattering sites (and/or increase the power factor), or incorporating any other material/process that improves electrical and/or thermal properties while improving mechanical properties as well. For example, at least one of power factor, Seebeck coefficient and electrical conductivity of the at least one compound with the spatial structure characteristic is greater than at least one of power factor, Seebeck coefficient and electrical conductivity of the at least one compound without the spatial structure characteristic.

More complex materials, e.g., with more than two phases, can be even more beneficial for ZT in certain embodiments. In certain embodiments, individual phases may address different aspects of improved TE properties, while the compound material exhibits the combination of improvements.

Advantageously, in the embodiments described, the individual TE materials are homogeneous. Although the materials themselves are homogeneous, in the advantageous embodiments, it should be apparent from the description above that two methods are used to improve the performance, where one method improves the ZT and the other reduces the thermal conductivity. Advantageously, where two methods are used, the first method does not or does not significantly degrade the improvement of the second method. Preferably, although some degradation caused by the first method on the improvement from the second method will not be such that the benefit of the second method is neutralized or made negligible by the practice of the first method. Similarly, advantageously, the second method does not or does not significantly degrade the improvement obtained by the first method, at least not so much that the benefit of the first method is neutralized or made negligible by the practice of the second method.

In certain embodiments, other manufacturing methods can be applied to the production of materials with lowered thermal conductivity and increased Power Factor. For example, in certain embodiments, the materials can be precipitated from solution using appropriate precursors, condensed from one or more vapor phases or cooled from one or more liquid phases. These methods may be combined in any advantageous manner. For example, a vapor phase can be condensed on one or more types of liquid droplets or on particles precipitated from liquids.

In certain embodiments, the improvements of either the increased Power Factor or the reduced thermal conductivity may be introduced to the TE compound, or to at least one phase of a multi-phase TE compound, by subjecting the compound to a variety of environmental factors affecting the spatial and electronic structures of the compound. An example of such an environmental factor is rapid quenching of the compound from one temperature to another, lower value (e.g. cooling the compound to at least one selected temperature at a selected rate). Another example of such a factor is applying magnetic and/or electric fields to the material. Yet another example is a mechanical force applied to the material. In a further example, the one or more spatial inhomogeneities are formed by embedding particles of at least a first compound in a matrix of at least a second compound. A combination of two or more of the external factors, applied simultaneously or sequentially, can yield further improvement of the thermoelectric properties in certain embodiments.

Various embodiments have been described above. Although the invention has been described with reference to these specific embodiments, the descriptions are intended to be illustrative and are not intended to be limiting. Various modifications and applications may occur to those skilled in the art without departing from the true spirit and scope of the invention as defined in the appended claims.

What is claimed is:

1. A thermoelectric material comprising at least one compound comprising at least one dopant such that the at least one compound comprises one or more portions having a Power Factor greater than a Power Factor of the at least one compound without the at least one dopant, wherein the at least one compound comprises a spatial structure characteristic such that the at least one compound has a lattice thermal conductivity coefficient less than a lattice thermal conductivity coefficient of the at least one compound without the spatial structure characteristic.

2. The thermoelectric material of claim 1, wherein the at least one compound with the spatial structure characteristic has a structural strength or stability greater than a structural strength or stability of the at least one compound without the spatial structure characteristic.

3. The thermoelectric material of claim 2, wherein the structural strength or stability is at least one of fracture toughness, hardness and yield strength.

4. The thermoelectric material of claim 2, wherein at least one of power factor, Seebeck coefficient and electrical conductivity of the at least one compound with the spatial structure characteristic is greater than at least one of power factor, Seebeck coefficient and electrical conductivity of the at least one compound without the spatial structure characteristic.

5. The thermoelectric material of claim 1, wherein the spatial structure characteristic comprises one or more spatial inhomogeneities.

6. The thermoelectric material of claim 5, wherein the one or more spatial inhomogeneities have a characteristic size comparable to phonon wavelengths contributing to the lattice thermal conductivity of the at least one compound.

7. The thermoelectric material of claim 5, wherein the one or more spatial inhomogeneities suppress propagation of phonons within the at least one compound.

8. The thermoelectric material of claim 5, wherein the one or more spatial inhomogeneities comprise composition variations of the at least one compound.

9. The thermoelectric material of claim 8, wherein the composition variations comprise phase separation of the at least one compound into at least two phases.

10. The thermoelectric material of claim 9, wherein the at least two phases are formed by spinodal decomposition.

11. The thermoelectric material of claim 9, wherein the at least two phases are formed by nucleation and growth.

12. The thermoelectric material of claim 11, wherein the nucleation occurs at grain boundaries.

13. The thermoelectric material of claim 5, wherein the one or more spatial inhomogeneities are formed by embedding particles of at least a first compound in a matrix of at least a second compound.

14. The thermoelectric material of claim 1, wherein the at least one dopant distorts the electronic DOS of the at least one compound.

15. The thermoelectric material of claim 1, wherein the at least one compound comprises electron filtering of at least a portion of the at least one compound.

16. The thermoelectric material of claim 1, wherein the spatial structure characteristic is formed by cooling the at least one compound to at least one selected temperature at a selected rate.

17. The thermoelectric material of claim 1, wherein the spatial structure characteristic is formed by applying at least one of an electrical field and a magnetic field to the at least one compound.

18. The thermoelectric material of claim 1, wherein the spatial structure characteristic is formed by grinding or ball milling the at least one compound.

19. The thermoelectric material of claim 1, wherein the at least one compound comprises a plurality of grains and the spatial structure characteristic comprises a minimum grain size such that substantially all of the grains of the at least one compound are larger than the minimum grain size.

20. The thermoelectric material of claim 19, wherein the minimum grain size is sufficiently large to preserve the bulk stoichiometry of the at least one compound.
